(19) United States
(12) Patent Application Publication
(10) Pub. No.: US 2022/0223556 A1
(43) Pub. Date: Jul. 14, 2022

(54) BALL PLACEMENT STRUCTURE AND PREPARATION PROCESS THEREOF

(71) Applicant: CHIPMORE TECHNOLOGY CORPORATION LIMITED, Suzhou City, Jiangsu Province (CN)

(72) Inventor: YAN MEI, Suzhou City, Jiangsu Province (CN)

(21) Appl. No.: 17/617,306

(22) PCT Filed: Oct. 21, 2020
(86) PCT No.: PCT/CN2020/122448

§ 371 Date: Dec. 8, 2021

(30) Foreign Application Priority Data
Mar. 13, 2020 (CN) 202010175541.3

(51) Int. Cl. H01L 23/00

(52) U.S. Cl. CPC H01L 24/13; H01L 24/11; H01L 24/03; H01L 24/05; H01L 2924/37001; H01L 2224/10145; H01L 2924/3841; H01L 2224/0401; H01L 2224/05582; H01L 2224/11013

(57) ABSTRACT

The present invention provides a ball placement structure and a preparation process thereof. The ball placement structure includes a substrate, a conductive layer, a passivation layer, a seed layer, and a metal layer which are stacked in sequence, wherein a plurality of solder balls is respectively placed onto the metal layer, and a retaining wall is disposed between any adjacent solder balls, and is configured to prevent bridging between the solder balls.

### TECHNICAL FIELD

The present invention relates to semiconductor integrated circuit manufacturing processes, and in particular to a small-pitch ball placement structure and a ball placement process.

### BACKGROUND

The ball grid array (BGA) packaging technology is such a surface mount technology applied to integrated circuits that an array is made at the bottom of a package substrate, and solder balls, as I/O terminals of the circuit, are interconnected with a printed circuit board (PCB), and has the advantages of high yield, a large number of pins, and simple equipment and the like.

In order to reduce the size of wafer-level IC packages, the distribution of solder balls on the surfaces of chips is becoming small-size and concentrated. At present, the industry limit gap (distance) between solder balls is about 40 um. When the distance between the solder balls is decreased constantly, the bridging between the balls appears due to the flowing of a soldering flux at the high temperature combined with molecular attraction, and thus a series of adverse effects is caused to devices. These adverse effects mainly lead to the reduction in the yield of the finished products and further may cause short circuiting of telecommunication surfaces.

Therefore, for the above technical problems, it is necessary to improve the ball placement structure and the packaging process to prevent the phenomenon of “bridging” arising from a decrease in the pitch between the solder balls and the flowing of a soldering flux.

### SUMMARY

The technical problems to be solved by the present invention are to overcome the problem of “bridging” between solder balls due to a decreased pitch between the solder balls and the flowing of a soldering flux, and thus increase the yield of finished products of the chip packaging process, and reduce the packaging cost.

The present invention provides a ball placement structure, which includes a substrate, a conductive layer, a passivation layer, a seed layer, and a metal layer which are stacked in sequence, wherein a plurality of solder balls is respectively placed on the metal layer, and a retaining wall is disposed between any adjacent solder balls, and is configured to prevent bridging between the solder balls.

As an optional technical solution, the retaining wall is disposed on the passivation layer and protrudes from the passivation layer.

As an optional technical solution, a dielectric layer is further included, wherein the dielectric layer is disposed on the passivation layer, and the retaining wall is disposed on the dielectric layer and protrudes from the dielectric layer.

As an optional technical solution, the retaining wall is made of a dielectric material.

As an optional technical solution, the dielectric material is polyimide.

As an optional technical solution, the section of the retaining wall between the placed solder balls is of a trapezoidal structure, a triangular structure or a rectangular structure.

As an optional technical solution, the section of the retaining wall between the placed solder balls is of a structure with a narrow top and a wide bottom.

As an optional technical solution, the substrate is a chip structure.

The present invention further provides a preparation process of a ball placement structure. The preparation process includes:

step S1: providing a substrate, and sequentially forming a seed layer and a metal layer on the substrate;

step S2, coating a dielectric material on the metal layer, wherein the dielectric material covers the substrate completely;

step S3, forming a retaining wall after exposing, developing and curing the dielectric material;

step S4, coating a soldering flux on the metal layer; and

step S5, placing a plurality of solder balls on the metal layer,

wherein the retaining wall is located between any adjacent solder balls.

The present invention provides another preparation process of a ball placement structure. The preparation process includes:

step S1: providing a substrate, and sequentially forming a dielectric layer and a metal layer on the substrate;

step S2, coating a dielectric material on the metal layer, wherein the dielectric material covers the substrate completely;

step S3, forming a retaining wall after exposing, developing and curing the dielectric material;

step S4, coating a soldering flux on the metal layer; and

step S5, placing a plurality of solder balls on the metal layer,

wherein the retaining wall is located between any adjacent solder balls.

Compared with the prior art, in the ball placement structure and the preparation process according to the present invention, by forming the retaining wall between any adjacent solder balls, the problem of bridging between the solder balls due to the flowing of the soldering flux and liquefaction of the solder balls when the solder balls are placed can be avoided, and thus the quality of the ball placement process is improved and the yield of finished products of the packaging process is increased. In the case where the size of the chip does not change, soldering points can be increased, thereby placing the solder balls at smaller pitches (the pitch between the balls is less than 40 um), or in the case where the number of soldering points on the chip does not change, the chip package size can be reduced as the pitch between the balls is reduced.

### BRIEF DESCRIPTION OF THE DRAWINGS

FIG. 1 is a schematic diagram of a ball placement structure in a first embodiment of the present invention;

FIG. 2A to FIG. 2E are schematic diagrams of a forming process of the ball placement structure in FIG. 1;

FIG. 3 is a schematic diagram of a ball placement structure in a second embodiment of the present invention;

FIG. 4A to FIG. 4H are schematic diagrams of a forming process of the ball placement structure in FIG. 3;

FIG. 5 is a flowchart of a preparation process of the ball placement structure in FIG. 1; and

FIG. 6 is a flowchart of a preparation process of the ball placement structure in FIG. 3.

### DETAILED DESCRIPTION

The present invention will be described in detail below with reference to specific embodiments shown in the accompanying drawings. However, these embodiments are not intended to limit the present invention, and changes of structures, methods or functions, made by a person of ordinary skill in the art according to these embodiments are included within the scope of protection of the present invention.

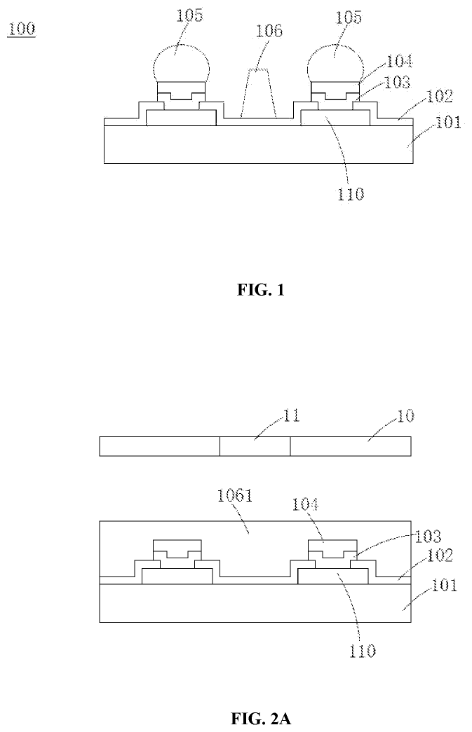

FIG. 1 is a schematic diagram of a ball placement structure in a first embodiment of the present invention.

Referring to FIG. 1, the ball placement structure 100 includes a substrate 101, conductive layers 110, a passivation layer 102, seed layers 103 and metal layers 104 which are stacked in sequence. A plurality of solder balls 105 is placed on the metal layers 104 respectively; and a retaining wall 106 is disposed between any adjacent solder balls 105 for preventing bridging between the solder balls 105.

In a preferred embodiment, the retaining wall 106 protrudes from the passivation layer 102.

In a preferred embodiment, the section of the retaining wall 106 takes the shape of a trapezoid; the width of the bottom of the trapezoid is about 33 μm; the height of the trapezoid does not exceed ⅔ of the ball height; and the width of the top of the trapezoid is about 15 μm.

In other embodiments of the present invention, the retaining wall may also have the other shape, such as a triangular structure or a rectangular structure, and most preferably a shape with a narrower upper portion and a wider lower portion. The wider lower portion makes the contact area between the retaining wall and the dielectric layer large, which is conducive to the stable contact between the retaining wall and the dielectric layer. With the narrower upper portion, when preventing the bridging between the solder balls, the retaining wall does not interfere with the solder balls.

In a preferred embodiment, the retaining wall 106 is made of a dielectric material, such as polyimide (PI), but is not limited thereto. In other embodiments of the present invention, the dielectric material may also be an inorganic material, such as silicon dioxide.

In this embodiment, the conductive layers 110 are covered with the passivation layer 102, openings are formed after the passivation layer 102 is patterned, and the conductive layers 110 are exposed from the openings; the seed layers 103 are formed in the opening through processes such as sputtering, so that the seed layers 103 are electrically connected to the conductive layers 110; and then the metal layers 104 are formed on the seed layers 103 through processes such as electroplating. The material of the metal layer 104 and the material of the seed layer 103 may be the same or different. In addition, the solder balls 105 are placed on the metal layers 104, so that electrical signals in the substrate 101 may be exported from the conductive layers 110, the seed layers 103, the metal layers 104 and the solder balls 105.

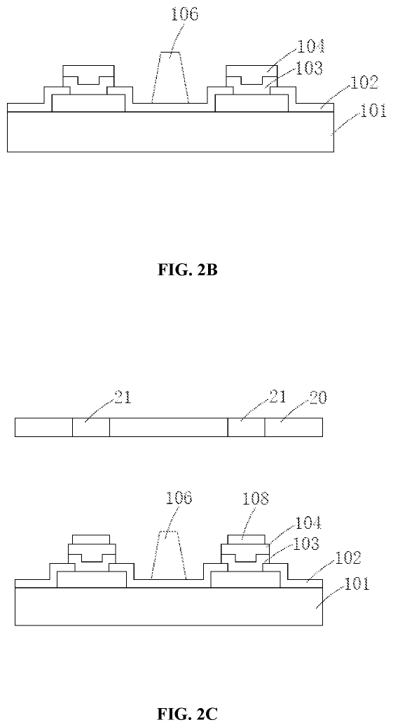

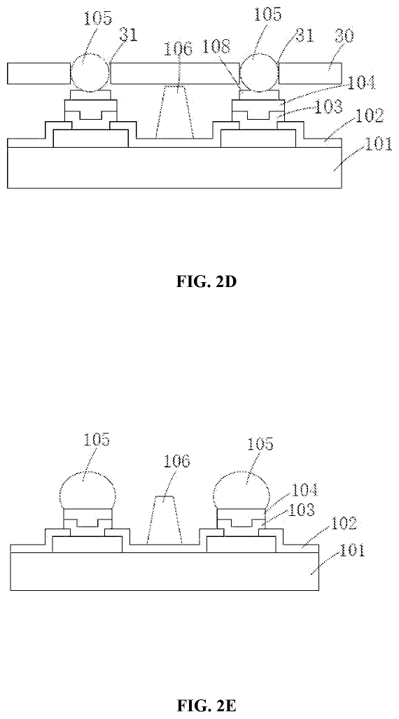

FIG. 2A to FIG. 2E are schematic diagrams of a forming process of the ball placement structure in FIG. 1.

Referring to FIGS. 2A and 2B, the substrate 101 is provided. The conductive layers 110, the passivation layer 102, the seed layers 103 and the metal layers 104 are sequentially formed on the substrate 101. The forming of the conductive layer 110, the passivation layer 102, the seed layer 103 and the metal layer 104 belongs to the technology known in the art, and may refer to the related description in the prior art. A dielectric material 1061 is coated on the metal layers 104. Preferably, the dielectric material 1061 completely covers the side of the substrate 101, on which the metal layers 104 are provided.

The retaining wall 106 is formed after the dielectric material 1061 is exposed, developed and cured. During the exposure and development process, a specific region, such as a region provided with no conductive layer 110 under the passivation layer 102, may be exposed through a plurality of first exposing holes 11 in a first mask 10 and then developed. In this embodiment, the retaining wall 106 protrudes from the passivation layer 102.

Referring to FIG. 2C, a soldering flux 108 is coated on the metal layer 104 to conveniently fix the solder balls 105. During coating, the soldering flux 108 is coated through a first screen 20. The first screen 20 is provided with a plurality of first openings 21 corresponding to the metal layers 104, and the soldering flux 108 is coated on the corresponding metal layer 104 from the first openings 21. The size of the first opening 21 is smaller than or equal to the size of the metal layer 104, which facilitates coating of the soldering flux 108 on the upper surface of the metal layer 104.

Referring to FIG. 2D, the solder balls 105 are placed on the soldering flux 108. Before the solder balls 105 are placed, the solder balls 105 are placed through a second screen 30 which is provided with a plurality of second openings 31 corresponding to the metal layers 104, and then, the plurality of solder balls 105 is placed on the soldering flux 108 from the plurality of second openings 31.

Referring to FIG. 2E, after the solder balls 105 are placed, the second screen 30 is removed. In order to promote the engagement between the solder balls 105 and the soldering flux 108 to enable the solder balls 105 and the metal layers 104 to be electrically connected firmly, a reflowing operation is performed at a set temperature (for example, the set temperature may be 220 degrees Celsius). During the reflowing operation, the solder balls 105 are liquefied at the set temperature, and the soldering flux 108 is liquefied to drive the solder balls 105 to move. Meanwhile, with the isolation effect of the retaining wall 106 disposed between adjacent solder balls 105, the phenomenon of “bridging” between the adjacent solder balls 105 due to the liquefaction of the solder balls themselves and the flowing of the soldering flux 108 will not appear.

It should be noted that in other embodiments of the present invention, the retaining wall may be formed before the seed layers and the metal layers are formed. For example, the passivation layer is prepared on the conductive layer on the substrate firstly; then the dielectric material, such as polyimide, is coated on the whole passivation layer; consequently, the retaining wall is formed after the dielectric material is exposed, developed, and cured; afterwards, the seed layers and the metal layers are formed by electroplating at openings of the passivation layer corresponding to the conductive layer; and finally, the soldering flux is coated on the metal layers through the first screen, the solder balls are placed on the soldering flux through the second screen, and the reflowing operation is performed, so that the solder balls are firmly connected to the metal layers.

In a preferred embodiment, the material of the passivation layer and the material of the retaining wall 106 may be the same or different.

In a preferred embodiment, the substrate 101 is a chip structure.

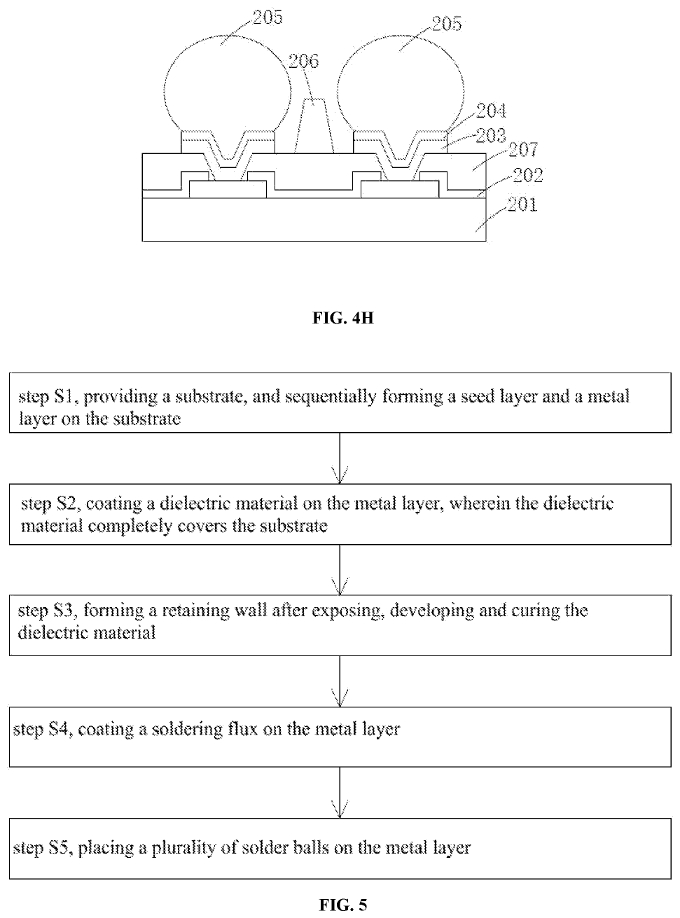

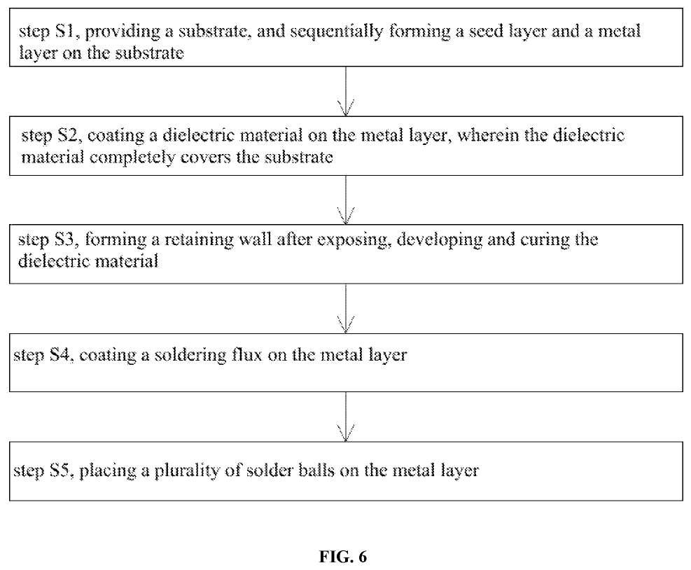

FIG. 5 is a flowchart of a preparation process of the ball placement structure 100 in the first embodiment of the present invention.

Referring to FIG. 5, the preparation process 300 includes the following steps.

In step S1, a substrate is provided, and a seed layer and a metal layer are sequentially formed on the substrate.

In step S2, a dielectric material is coated on the metal layer, wherein the dielectric material completely covers the substrate.

In step S3, a retaining wall is formed after the dielectric material is exposed, developed and cured.

In step S4, a soldering flux is coated on the metal layer.

In step S5, a plurality of solder balls is placed on the metal layer.

In a preferred embodiment, the retaining wall is located between any adjacent solder balls.

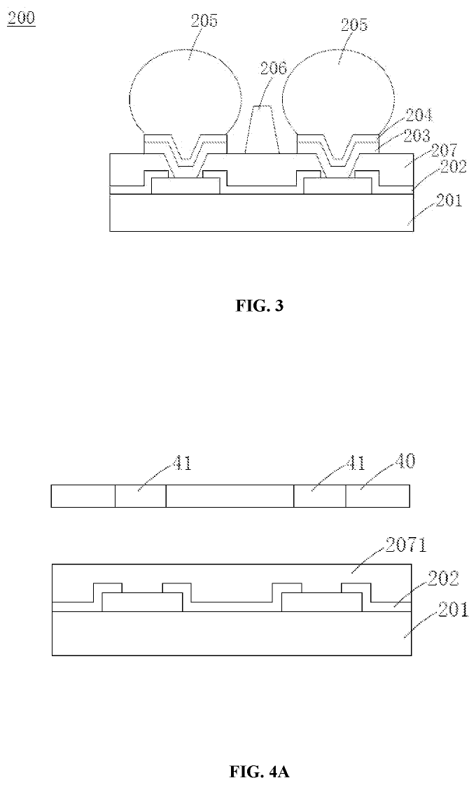

FIG. 3 is a schematic diagram of a ball placement structure in a second embodiment of the present invention.

Referring to FIG. 3, the ball placement structure 200 in the second embodiment of the present invention differs from the ball placement structure 100 in that a retaining wall 206 in the ball placement structure 200 is formed on a dielectric layer 207 above a passivation layer 202.

Specifically, the ball placement structure 200 includes a substrate 201, conductive layers 210, the passivation layer 202, and seed layers 203 which are stacked in sequence. Solder balls 205 are electrically connected to the seed layers 203 through metal layers 204. The ball placement structure 200 further includes the dielectric layer 207 on the passivation layer 202, and the retaining wall 206 is disposed on the dielectric layer 207, protrudes from the dielectric layer 207, and is located between any adjacent solder balls 205 to prevent bridging between the solder balls 205.

In a preferred embodiment, the section of the retaining wall 206 is trapezoidal.

In other embodiments of the present invention, the retaining wall may also have the other shape, such as a triangular structure or a rectangular structure, and most preferably the shape with a narrower upper portion and a wider lower portion. With the wider lower portion, the contact area between the retaining wall and a protecting layer is large, which is conducive to the stable contact between the retaining wall and the protecting layer; and the narrower upper portion prevents the retaining wall from interfering with the solder balls while preventing bridging between the solder balls.

In a preferred embodiment, the retaining wall 206 is made of a dielectric material, such as polyimide (PI), but is not limited thereto. In other embodiments of the present invention, the dielectric material may also be an inorganic material, such as silicon dioxide.

In this embodiment, the conductive layer 210 is covered with the passivation layer 202 and the dielectric layer 207. Openings are formed after the passivation layer 202 and the dielectric layer 207 are exposed and developed, so that the conductive layer 210 is exposed from the openings; the seed layers 203 are formed in the openings through processes such as sputtering, and are electrically connected to the conductive layer 210; and then the metal layers 204 are formed on the seed layers 203 through processes such as electroplating. The material of the metal layer 204 and the material of the seed layer 203 may be the same or different. In addition, the solder balls 205 are placed on the metal layers 204, so that electrical signals in the substrate 201 are exported from the conductive layer 210, the seed layers 203, the metal layers 204 and the solder balls 205.

In a preferred embodiment, the dielectric layer 207 may be made of an inorganic material and/or an organic material.

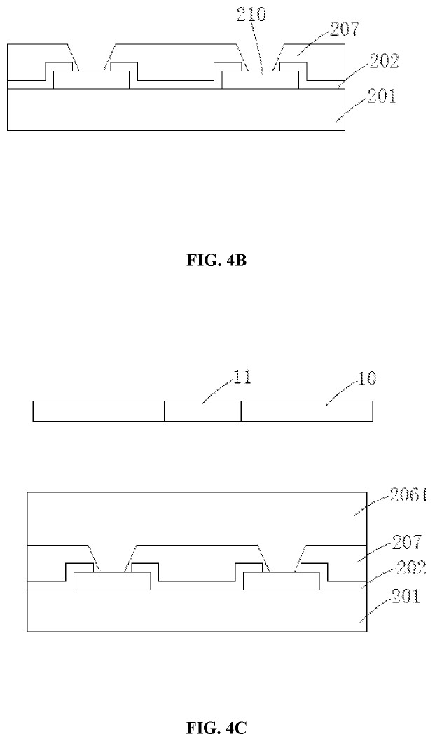

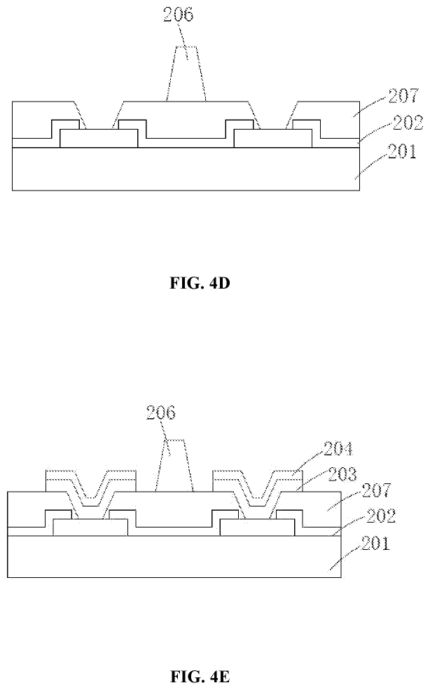

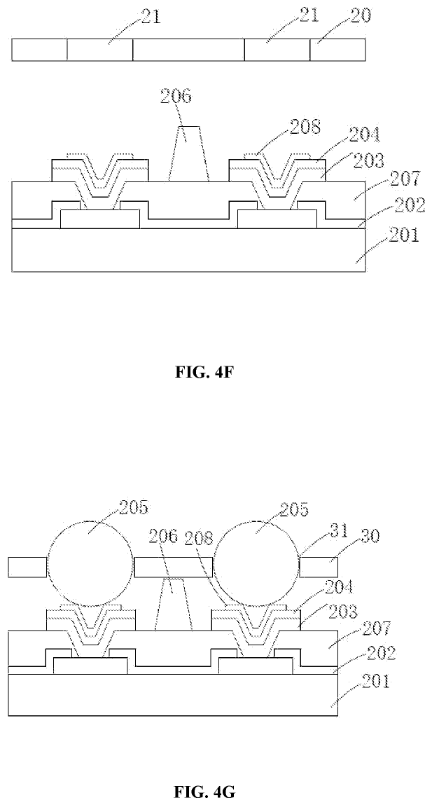

FIG. 4A to FIG. 4H are schematic diagrams of a forming process of the ball placement structure in FIG. 3. The patterns with the same reference numbers in FIG. 4A to FIG. 4H as those in FIG. 2A to FIG. 2E have similar functions, and will not be repeated herein.

Referring to FIGS. 4A and 4B, the substrate 201 is provided; the conductive layers 210 and the passivation layer 202 are sequentially formed on the substrate 201; a protecting material 2071 is coated on the passivation layer 202, and openings are formed after the protecting material 2071 is exposed and developed, and the conductive layers 210 are exposed from the openings; and then the dielectric layer 207 is formed through a curing process. During the exposure and development process, the openings are formed after a specific region of the protecting material 2071 is exposed through a plurality of second exposing holes 41 in a second mask 40 and then developed. The specific region of the protecting material 2071 corresponds to the position of the conductive layers 210 on the substrate 201.

Referring to FIGS. 4C and 4D, a dielectric material 2061 is coated on the dielectric layer 207, and the retaining wall 206 is formed after the dielectric material 2061 is exposed, developed and cured. During the exposure and development process, a specific region of the dielectric material 2061 may be exposed through a plurality of first exposing holes 11 in a first mask 10 and then developed and cured to form the retaining wall 206. The specific region of the dielectric material 2061 is, for example, a region at the lower portion of the dielectric material 2061 without conductive layer 210. In this embodiment, the retaining wall 206 protrudes from the dielectric layer 207.

Referring to FIG. 4E, the seed layers 203 are formed by electroplating in the openings of the dielectric layer 207 and are electrically connected to the metal layers 204; and then the metal layers 204 are formed on the seed layers 203.

Referring to FIG. 4F, the soldering flux 208 is firstly coated on the metal layers 204 to conveniently fix the solder balls 205. During coating, the soldering flux 208 is coated through a first screen 20. The first screen 20 is provided with a plurality of first openings 21 corresponding to the metal layers 204, and the soldering flux 208 is coated on the corresponding metal layers 204 from the first openings 21. Preferably, the size of the first opening 21 is smaller than or equal to the size of the metal layer 204, which facilitates coating of the soldering flux 208 on the upper surface of the metal layer 204.

Referring to FIG. 4G, the solder balls 205 are placed on the soldering flux 208. Before the solder balls 205 are placed, the solder balls 205 are placed through a second screen 30 which is provided with a plurality of second openings 31 corresponding to the metal layers 204, and the plurality of solder balls 205 is placed on the soldering flux 208 from the second openings 31. In this embodiment, the retaining wall 206 is disposed between any adjacent solder balls 205.

Referring to FIG. 4H, after the solder balls 205 are placed, the second screen 30 is removed. In order to promote the engagement between the solder balls 105 and the soldering flux 208 to enable the solder balls 205 and the metal layer 204 to be electrically connected firmly, a reflowing operation is performed at a set temperature (for example, the set temperature may be 220 degrees Celsius). During the reflowing operation, the solder balls 205 are liquefied at the set temperature, and the soldering flux 208 is liquefied to drive the solder balls 105 to move. Meanwhile, with the isolation effect of the retaining wall 206 disposed between adjacent solder balls 205, the phenomenon of “bridging” between the adjacent solder balls 205 due to the liquefaction of the solder balls themselves and the flowing of the soldering flux 208 will not appear.

It should be noted that in the other embodiments of the present invention, the retaining wall may also be formed after the seed layer and the metal layer are formed. That is, the conductive layer, the passivation layer, the dielectric layer, the seed layers, and the metal layers are sequentially formed on the substrate; then the dielectric material, such as polyimide, is coated on the metal layers; afterwards, the retaining wall is formed after the dielectric material is exposed, developed and cured; and finally, the soldering flux is coated on the metal layers through the first screen, and the solder balls are placed on the soldering flux through the second screen. The reflowing operation is performed, so that the solder balls are firmly connected to the metal layers.

In a preferred embodiment, the passivation layer 202, the dielectric layer 207, and the retaining wall 206 may be respectively made of the same material or different materials.

In a preferred embodiment, the substrate 201 is a chip structure.

FIG. 6 is a flowchart of a preparation process of the ball placement structure 200 in the second embodiment of the present invention.

Referring to FIG. 6, the preparation process 400 includes the following steps.

In step S1, a substrate is provided, and a dielectric layer and a metal layer are formed on the substrate.

In step S2, a dielectric material is coated on the metal layer, wherein the dielectric material completely covers the substrate.

In step S3, a retaining wall is formed after the dielectric material is exposed, developed and cured.

In step S4, a soldering flux is coated on the metal layer.

In step S5, a plurality of solder balls is placed on the metal layer.

In a preferred embodiment, the retaining wall is located between any adjacent solder balls.

In summary, for the ball placement structure and the preparation process according to the present invention, the problem of bridging between the solder balls due to the flowing of soldering flux and liquefaction of the solder balls when the solder balls are placed can be avoided, and thus the quality of the ball placement process is improved and the yield rate of the finished products of the packaging process is increased. In the case where the size of the chip does not change, soldering points can be increased, thereby placing solder balls at smaller pitches (the pitch between the balls is less than 40 um). Or, in the case where the number of soldering points on the chip does not change, the chip package size can be reduced as the pitch between the balls is reduced.

The above detailed description only aims to specifically illustrate the feasible embodiments of the present invention, and is not intended to limit the scope of protection of the present invention. Equivalent embodiments or modifications thereof made without departing from the spirit of the present invention shall fall within the scope of protection of the present invention.

What is claimed is:

1. A ball placement structure, comprising a substrate, a conductive layer, a passivation layer, a seed layer, and a metal layer which are stacked in sequence, a plurality of solder balls being respectively placed on the metal layer; wherein
a retaining wall is disposed between any adjacent solder balls, and is configured to prevent bridging between the solder balls.

2. The ball placement structure according to claim 1, wherein the retaining wall is disposed on the passivation layer and protrudes from the passivation layer.

3. The ball placement structure according to claim 1, further comprising a dielectric layer, wherein the dielectric layer is disposed on the passivation layer, and the retaining wall is disposed on the passivation layer and protrudes from the dielectric layer.

4. The ball placement structure according to claim 1, wherein the retaining wall is made of a dielectric material.

5. The ball placement structure according to claim 4, wherein the dielectric material is polyimide.

6. The ball placement structure according to claim 1, wherein a section of the retaining wall between the placed solder balls is of a trapezoidal structure, a triangular structure or a rectangular structure.

7. The ball placement structure according to claim 1, wherein a section of the retaining wall between the placed solder balls is of a structure with a narrow top and a wide bottom.

8. The ball placement structure according to claim 1, wherein the substrate is a chip structure.

9. A preparation process of a ball placement structure, comprising:
step S1: providing a substrate, and sequentially forming a seed layer and a metal layer on the substrate;
step S2, coating a dielectric material on the metal layer, wherein the dielectric material completely covers the substrate;
step S3, forming a retaining wall after exposing, developing and curing the dielectric material;
step S4, coating a soldering flux on the metal layer; and
step S5, placing a plurality of solder balls on the metal layer;
wherein the retaining wall is located between any adjacent solder balls.

10. A preparation process of a ball placement structure, comprising:
step S1: providing a substrate, and forming a dielectric layer and a metal layer on the substrate;
step S2, coating a dielectric material on the metal layer, wherein the dielectric material completely covers the substrate;
step S3, forming a retaining wall after exposing, developing and curing the dielectric material;
step S4, coating a soldering flux on the metal layer; and
step S5, placing a plurality of solder balls on the metal layer;
wherein the retaining wall is located between any adjacent solder balls.
